(19) United States
(12) Patent Application Publication
(10) Pub. No.: US 2016/0366786 A1
(43) Pub. Date: Dec. 15, 2016

(54) LIQUID SUPPLY MECHANISM AND LIQUID COOLING SYSTEM

(71) Applicant: COOLER MASTER CO., LTD., New Taipei City (TW)

(72) Inventors: Pen-Hung Liao, New Taipei City (TW); Shih-Wei Huang, New Taipei City (TW); Hsin-Hung Chen, New Taipei City (TW)

(21) Appl. No.: 14/736,246

(22) Filed: Jun. 10, 2015

(51) Int. Cl. H05K 7/20; B67D 7/02; B67D 3/00

(52) U.S. Cl. CPC H05K 7/20272; B67D 3/0025; B67D 7/0294

(57) ABSTRACT

A liquid supply mechanism includes a casing, a cover and a plunger. The casing has a liquid outlet. The cover is connected to the casing. A chamber is formed between the casing and the cover. The chamber communicates with the liquid outlet. The cover has a first magnetic area. The plunger is movably disposed in the chamber. The plunger has a second magnetic area. A position of the first magnetic area is corresponding to a position of the second magnetic area and a magnetic pole of an end of the first magnetic area facing the second magnetic area is identical to a magnetic pole of an end of the second magnetic area facing the first magnetic area, such that a magnetic repulsive force is generated between the first magnetic area and the second magnetic area.

### BACKGROUND OF THE INVENTION

### 1. Field of the Invention

The invention relates to a liquid supply mechanism and a liquid cooling system and, more particularly, to a liquid supply mechanism capable of supplying a cooling liquid to a liquid cooling system in time when the cooling liquid is insufficient.

### 2. Description of the Prior Art

In general, a liquid cooling system essentially consists of a liquid cooling head, a radiator, a pump and a liquid storage box connected through a plurality of tubes. When the liquid cooling system is dissipating heat from an electronic component, the pump transports a cooling liquid to the liquid cooling head, the cooling liquid absorbs the heat generated by the electronic component, and then the radiator cools the cooling liquid. After the liquid cooling system is used for a long time, the cooling liquid will reduce due to vaporization, such that the cooling liquid may be insufficient. If the user does not supply the cooling liquid in time, the liquid cooling system may be damaged due to insufficient cooling liquid.

### SUMMARY OF THE INVENTION

The invention provides a liquid supply mechanism and a liquid cooling system equipped with the liquid supply mechanism, so as to solve the aforesaid problems.

According to an embodiment of the invention, a liquid supply mechanism comprises a casing, a cover and a plunger. The casing has a liquid outlet. The cover is connected to the casing. A chamber is formed between the casing and the cover. The chamber communicates with the liquid outlet. The cover has a first magnetic area. The plunger is movably disposed in the chamber. The plunger has a second magnetic area. A position of the first magnetic area is corresponding to a position of the second magnetic area and a magnetic pole of an end of the first magnetic area facing the second magnetic area is identical to a magnetic pole of an end of the second magnetic area facing the first magnetic area, such that a magnetic repulsive force is generated between the first magnetic area and the second magnetic area.

According to another embodiment of the invention, a liquid cooling system comprises a liquid cooling head, a radiator, a pump, a liquid storage box, a plurality of tubes and a liquid supply mechanism. The tubes are connected between the liquid cooling head, the radiator, the pump and the liquid storage box. The liquid supply mechanism is selectively connected to one of the liquid cooling head, the radiator, the pump, the liquid storage box and the tubes. The liquid supply mechanism comprises a casing, a cover and a plunger. The casing has a liquid outlet. The cover is connected to the casing. A chamber is formed between the casing and the cover. The chamber communicates with the liquid outlet. The cover has a first magnetic area. The plunger is movably disposed in the chamber. The plunger has a second magnetic area. A position of the first magnetic area is corresponding to a position of the second magnetic area and a magnetic pole of an end of the first magnetic area facing the second magnetic area is identical to a magnetic pole of an end of the second magnetic area facing the first magnetic area, such that a magnetic repulsive force is generated between the first magnetic area and the second magnetic area.

According to an embodiment of the invention, a liquid supply mechanism comprises a casing, a cover and a plunger. The casing has a liquid outlet and a first magnetic area. The cover is connected to the casing. A chamber is formed between the casing and the cover. The chamber communicates with the liquid outlet. The plunger is movably disposed in the chamber. The plunger has a second magnetic area. A position of the first magnetic area is corresponding to a position of the second magnetic area and a magnetic pole of an end of the first magnetic area facing the second magnetic area is opposite to a magnetic pole of an end of the second magnetic area facing the first magnetic area, such that a magnetic attraction force is generated between the first magnetic area and the second magnetic area.

According to another embodiment of the invention, a liquid cooling system comprises a liquid cooling head, a radiator, a pump, a liquid storage box, a plurality of tubes and a liquid supply mechanism. The tubes are connected between the liquid cooling head, the radiator, the pump and the liquid storage box. The liquid supply mechanism is selectively connected to one of the liquid cooling head, the radiator, the pump, the liquid storage box and the tubes. The liquid supply mechanism comprises a casing, a cover and a plunger. The casing has a liquid outlet and a first magnetic area. The cover is connected to the casing. A chamber is formed between the casing and the cover. The chamber communicates with the liquid outlet. The plunger is movably disposed in the chamber. The plunger has a second magnetic area. A position of the first magnetic area is corresponding to a position of the second magnetic area and a magnetic pole of an end of the first magnetic area facing the second magnetic area is opposite to a magnetic pole of an end of the second magnetic area facing the first magnetic area, such that a magnetic attraction force is generated between the first magnetic area and the second magnetic area.

As mentioned in the above, the liquid supply mechanism of the invention is selectively connected to one of the liquid cooling head, the radiator, the pump, the liquid storage box and the tubes. When the cooling liquid reduces and then the hydraulic pressure of the liquid cooling system reduces, the liquid supply mechanism utilizes the magnetic repulsive force or the magnetic attraction force to drive the plunger to move, so as to inject the cooling liquid from the chamber into the liquid cooling system. In other words, the liquid supply mechanism of the invention can supply the cooling liquid to the liquid cooling system automatically when the cooling liquid is insufficient, so as to prevent the liquid cooling system from being damaged due to insufficient cooling liquid.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a liquid cooling system according to an embodiment of the invention.

FIG. 2 is a schematic view illustrating a liquid supply mechanism according to an embodiment of the invention.

FIG. 3 is an exploded view illustrating the liquid supply mechanism shown in FIG. 2.

FIG. 4 is an exploded view illustrating the liquid supply mechanism shown in FIG. 2 from another viewing angle.

FIG. 5 is a cross-sectional view illustrating the liquid supply mechanism shown in FIG. 2 along line X-X.

FIG. 6 is a cross-sectional view illustrating a liquid supply mechanism according to another embodiment of the invention.

FIG. 7 is a cross-sectional view illustrating a liquid supply mechanism according to another embodiment of the invention.

### DETAILED DESCRIPTION

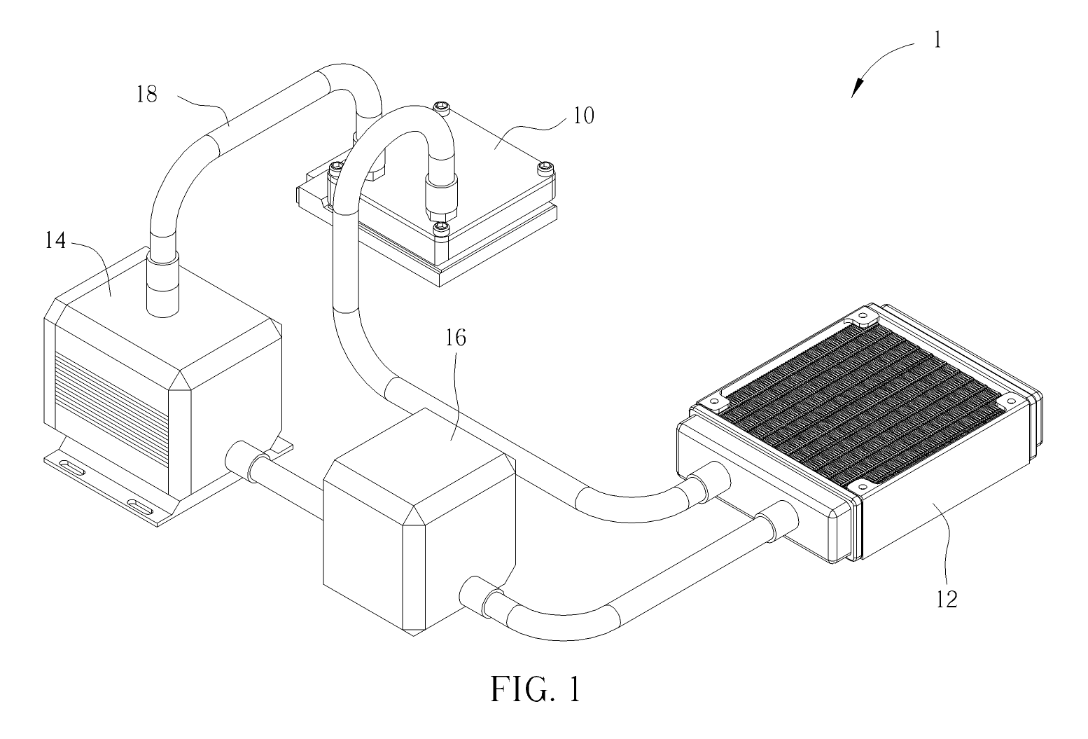

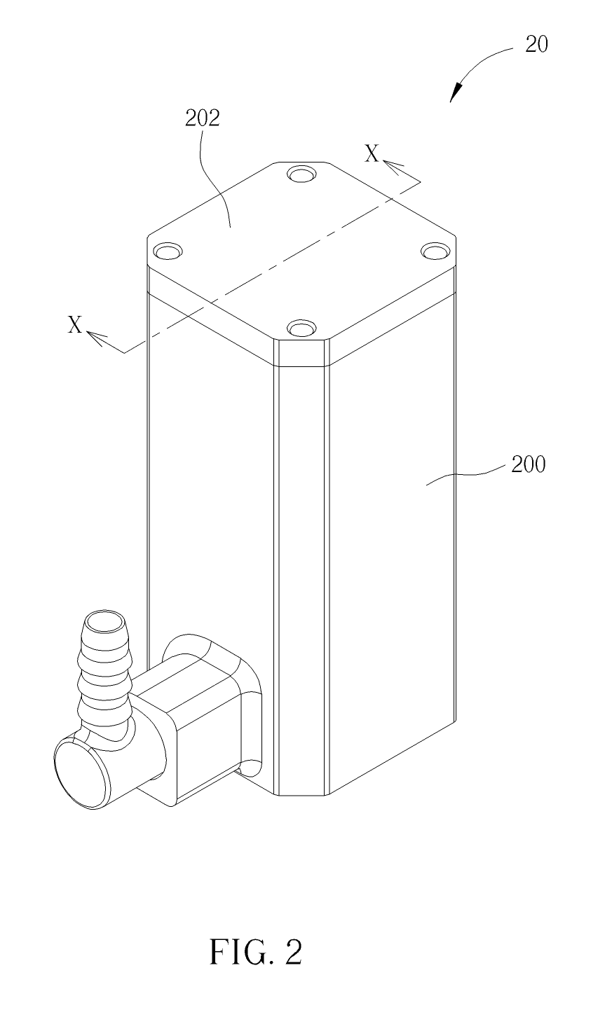

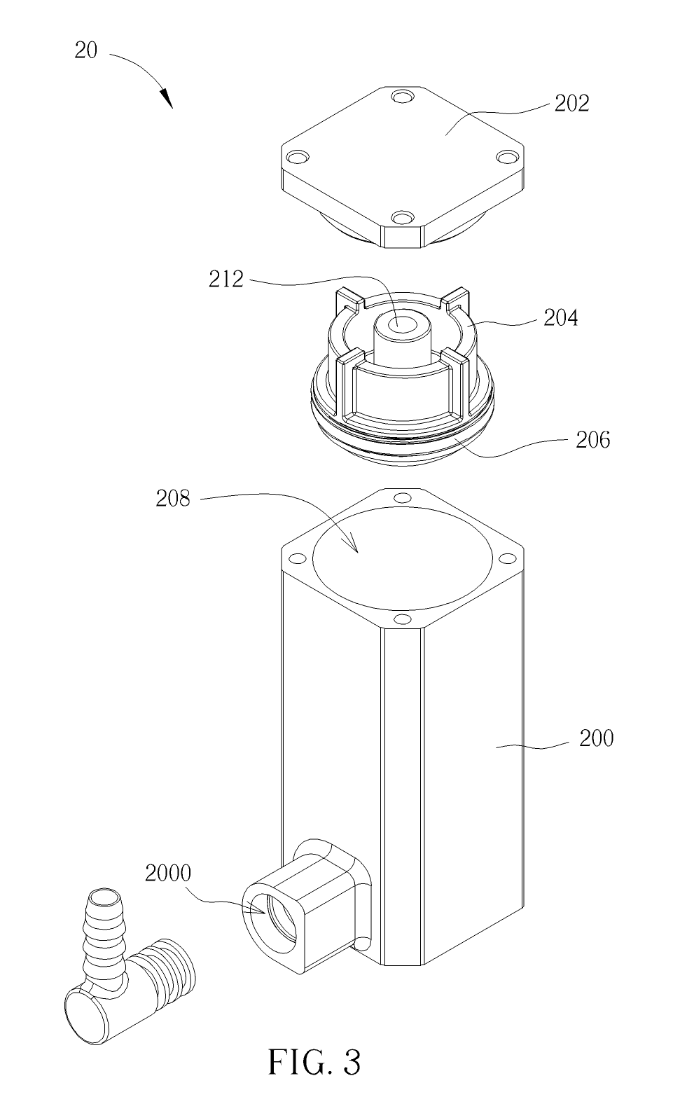

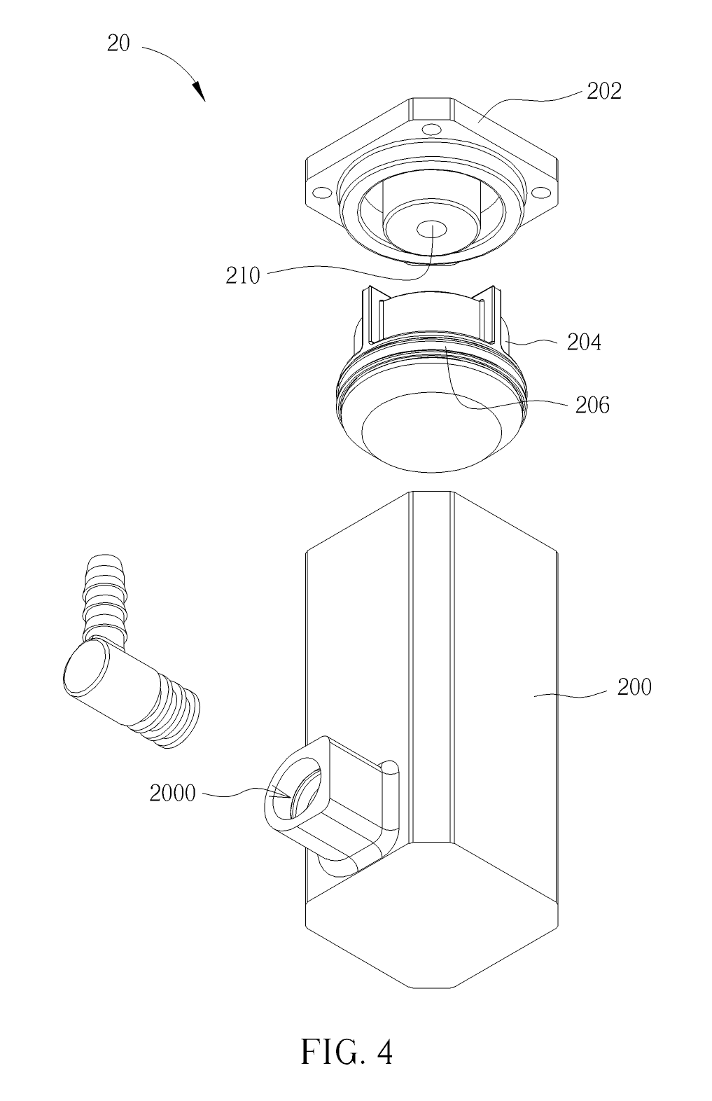

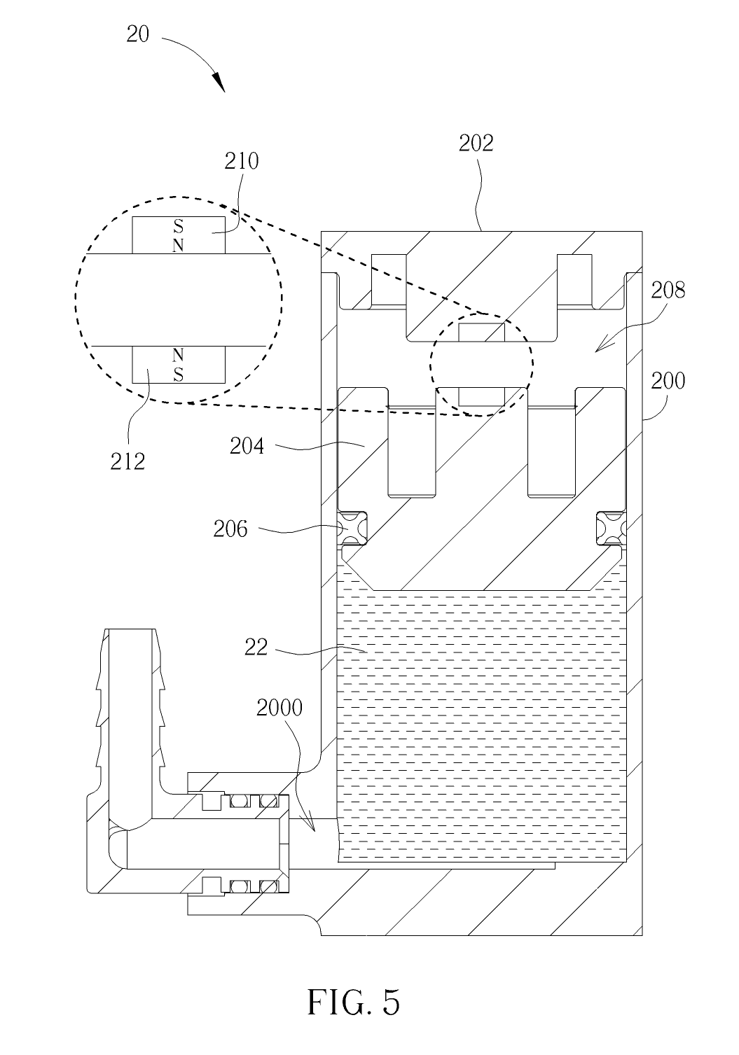

Referring to FIGS. 1 to 5, FIG. 1 is a schematic view illustrating a liquid cooling system 1 according to an embodiment of the invention, FIG. 2 is a schematic view illustrating a liquid supply mechanism 20 according to an embodiment of the invention, FIG. 3 is an exploded view illustrating the liquid supply mechanism 20 shown in FIG. 2, FIG. 4 is an exploded view illustrating the liquid supply mechanism 20 shown in FIG. 2 from another viewing angle, and FIG. 5 is a cross-sectional view illustrating the liquid supply mechanism 20 shown in FIG. 2 along line X-X.

As shown in FIG. 1, the liquid cooling system 1 comprises a liquid cooling head 10, a radiator 12, a pump 14, a liquid storage box 16 and a plurality of tubes 18. The tubes 18 are connected between the liquid cooling head 10, the radiator 12, the pump 14 and the liquid storage box 16 and used for transporting a cooling liquid between the liquid cooling head 10, the radiator 12, the pump 14 and the liquid storage box 16. The cooling liquid (not shown in FIG. 1) is filled in the liquid cooling head 10, the radiator 12, the pump 14, the liquid storage box 16 and the tubes 18. When the liquid cooling system 1 of the invention is used for dissipating heat from an electronic component (not shown), the liquid cooling head 10 of the liquid cooling system 1 is attached on the electronic component. The pump 14 transports the cooling liquid to the liquid cooling head 10, the cooling liquid absorbs the heat generated by the electronic component, and then the radiator 12 cools the cooling liquid.

As shown in FIGS. 2 to 5, the liquid cooling system 1 further comprises a liquid supply mechanism 20, wherein the liquid supply mechanism 20 may be selectively connected to one of the liquid cooling head 10, the radiator 12, the pump 14, the liquid storage box 16 and the tubes 18 shown in FIG. 1 according to practical applications.

The liquid supply mechanism 20 comprises a casing 200, a cover 202, a plunger 204 and a washer 206. The casing 200 has a liquid outlet 2000. The cover 202 is connected to the casing 200 and a chamber 208 is formed between the casing 200 and the cover 202. The chamber 208 communicates with the liquid outlet 2000 and contains a cooling liquid 22. In practical applications, the cooling liquid 22 may be water or other liquids. The plunger 204 is movably disposed in the chamber 208. The washer 206 is sleeved on an outer wall of the plunger 204 and abuts against an inner wall of the casing 200. Accordingly, the washer 206 can prevent the cooling liquid 22 from entering a space between the cover 202 and the plunger 204.

When the liquid supply mechanism 20 is connected to one of the liquid cooling head 10, the radiator 12, the pump 14, the liquid storage box 16 and the tubes 18 shown in FIG. 1, the liquid outlet 2000 communicates with one of the liquid cooling head 10, the radiator 12, the pump 14, the liquid storage box 16 and the tubes 18, such that the cooling liquid 22 of the chamber 208 can be injected into one of the liquid cooling head 10, the radiator 12, the pump 14, the liquid storage box 16 and the tubes 18 through the liquid outlet 2000.

The cover 202 has a first magnetic area 210 and the plunger 204 has a second magnetic area 212, wherein a position of the first magnetic area 210 is corresponding to a position of the second magnetic area 212. As shown in FIG. 5, a magnetic pole of an end of the first magnetic area 210 facing the second magnetic area 212 is identical to a magnetic pole of an end of the second magnetic area 212 facing the first magnetic area 210, such that a magnetic repulsive force is generated between the first magnetic area 210 and the second magnetic area 212. It should be noted that the magnetic pole of an end of the first magnetic area 210 facing the second magnetic area 212 and the magnetic pole of an end of the second magnetic area 212 facing the first magnetic area 210 both may be north magnetic poles or south magnetic poles according to practical applications. In this embodiment, the first magnetic area 210 may be a magnet or an electromagnet, and the second magnetic area 212 may be a magnet.

When the liquid supply mechanism 20 is assembled completely and the chamber 208 contains the cooling liquid 22, the magnetic repulsive force generated between the first magnetic area 210 and the second magnetic area 212 balances with the hydraulic pressure generated by the cooling liquid 22. At this time, the plunger 204 stays static in the chamber 208 . When the cooling liquid of the liquid cooling system 1 reduces and then the hydraulic pressure reduces, the magnetic repulsive force generated between the first magnetic area 210 and the second magnetic area 212 will push the plunger 204 to move, so as to inject the cooling liquid 22 from the chamber 208 into one of the liquid cooling head 10, the radiator 12, the pump 14, the liquid storage box 16 and the tubes 18. In other words, the liquid supply mechanism 20 of the invention can supply the cooling liquid to the liquid cooling system 1 automatically when the cooling liquid is insufficient, so as to prevent the liquid cooling system 1 from being damaged due to insufficient cooling liquid. When the magnetic repulsive force generated between the first magnetic area 210 and the second magnetic area 212 balances with the hydraulic pressure generated by the cooling liquid 22 again, the plunger 204 stops moving.

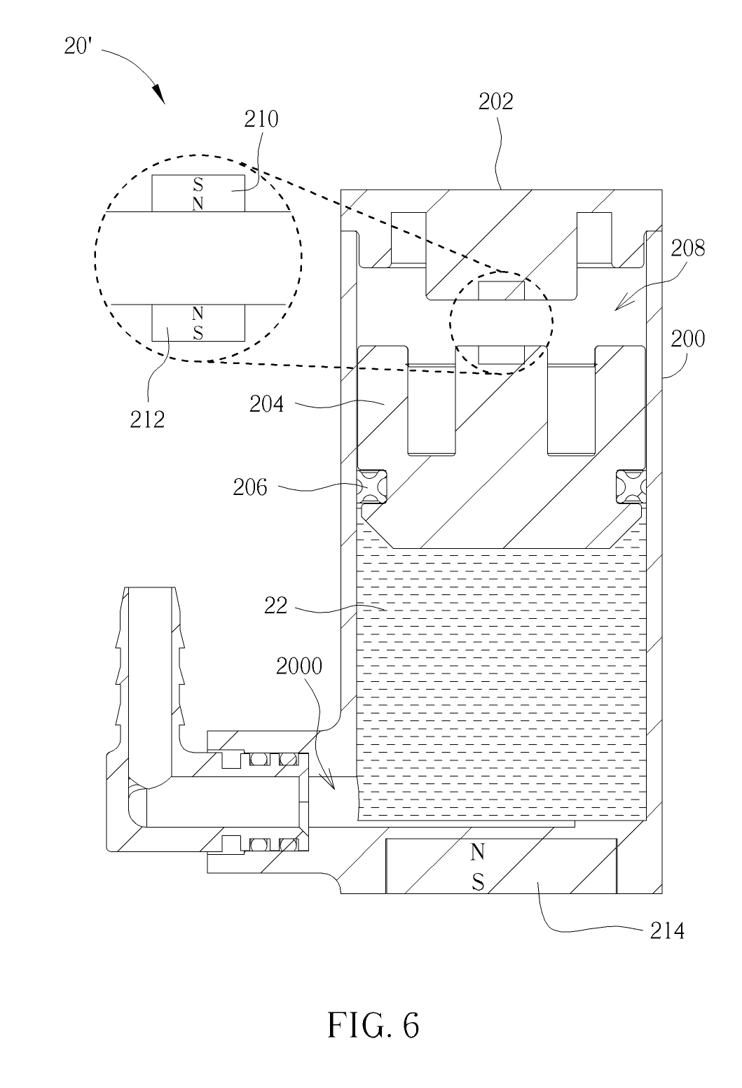

Referring to FIG. 6, FIG. 6 is a cross-sectional view illustrating a liquid supply mechanism 20′ according to another embodiment of the invention. The difference between the liquid supply mechanism 20′ and the aforesaid liquid supply mechanism 20 is that the casing 200 of the liquid supply mechanism 20′ has a third magnetic area 214, wherein the second magnetic area 212 is located between the first magnetic area 210 and the third magnetic area 214. As shown in FIG. 6, a magnetic pole of an end of the second magnetic area 212 facing the third magnetic area 214 is opposite to a magnetic pole of an end of the third magnetic area 214 facing the second magnetic area 212, such that a magnetic attraction force is generated between the second magnetic area 212 and the third magnetic area 214. It should be noted that the magnetic pole of an end of the second magnetic area 212 facing the third magnetic area 214 may be a north magnetic pole or a south magnetic pole, and the magnetic pole of an end of the third magnetic area 214 facing the second magnetic area 212 may be a south magnetic pole or a north magnetic pole correspondingly according to practical applications. In this embodiment, the third magnetic area 214 may be a magnetic induction material (e.g. iron or other metals), a magnet or an electromagnet. It should be noted that the same elements in FIG. 6 and FIG. 5 are represented by the same numerals, so the repeated explanation will not be depicted herein again.

When the liquid supply mechanism 20′ is assembled completely and the chamber 208 contains the cooling liquid 22, the magnetic repulsive force generated between the first magnetic area 210 and the second magnetic area 212 and the magnetic attraction force generated between the second magnetic area 212 and the third magnetic area 214 balance with the hydraulic pressure generated by the cooling liquid 22. At this time, the plunger 204 stays static in the chamber 208. When the cooling liquid of the liquid cooling system 1 reduces and then the hydraulic pressure reduces, the magnetic repulsive force generated between the first magnetic area 210 and the second magnetic area 212 will push the plunger 204 to move and the second magnetic area 212 and the magnetic attraction force generated between the second magnetic area 212 and the third magnetic area 214 will pull the plunger 204 to move, so as to inject the cooling liquid 22 from the chamber 208 into one of the liquid cooling head 10, the radiator 12, the pump 14, the liquid storage box 16 and the tubes 18. When the magnetic repulsive force generated between the first magnetic area 210 and the second magnetic area 212 and the magnetic attraction force generated between the second magnetic area 212 and the third magnetic area 214 balance with the hydraulic pressure generated by the cooling liquid 22 again, the plunger 204 stops moving.

In this embodiment, the third magnetic area 214 may be detachably disposed on a bottom of the casing 200. When a user wants to supply the cooling liquid 22 to the liquid supply mechanism 20′, the user may detach the third magnetic area 214 from the bottom of the casing 200 first, so as to prevent the magnetic attraction force generated between the second magnetic area 212 and the third magnetic area 214 from hindering the supply of the cooling liquid 22.

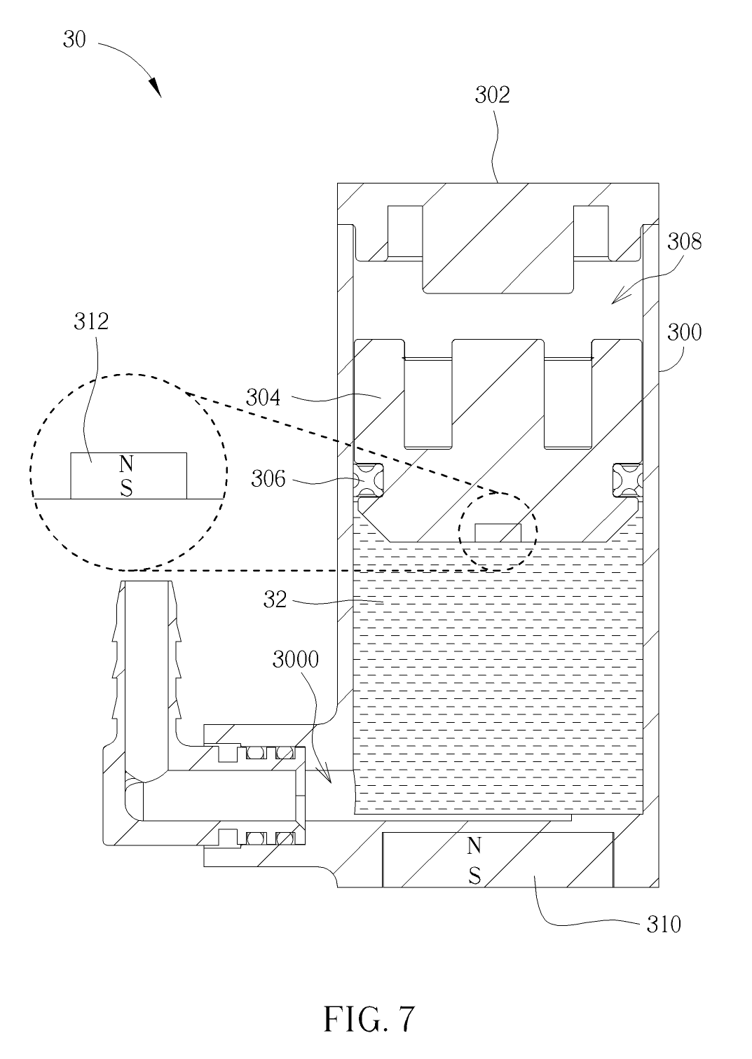

Referring to FIG. 7, FIG. 7 is a cross-sectional view illustrating a liquid supply mechanism 30 according to another embodiment of the invention. As shown in FIG. 7, the liquid supply mechanism 30 comprises a casing 300, a cover 302, a plunger 304 and a washer 306. The casing 300 has a liquid outlet 3000. The cover 302 is connected to the casing 300 and a chamber 308 is formed between the casing 300 and the cover 302. The chamber 308 communicates with the liquid outlet 3000 and contains a cooling liquid 32 . In practical applications, the cooling liquid 32 may be water or other liquids. The plunger 304 is movably disposed in the chamber 308. The washer 306 is sleeved on an outer wall of the plunger 304 and abuts against an inner wall of the casing 300. Accordingly, the washer 306 can prevent the cooling liquid 32 from entering a space between the cover 302 and the plunger 304.

When the liquid supply mechanism 30 is connected to one of the liquid cooling head 10, the radiator 12, the pump 14, the liquid storage box 16 and the tubes 18 shown in FIG. 1, the liquid outlet 3000 communicates with one of the liquid cooling head 10, the radiator 12, the pump 14, the liquid storage box 16 and the tubes 18, such that the cooling liquid 32 of the chamber 308 can be injected into one of the liquid cooling head 10, the radiator 12, the pump 14, the liquid storage box 16 and the tubes 18 through the liquid outlet 3000.

The casing 300 has a first magnetic area 310 and the plunger 304 has a second magnetic area 312, wherein a position of the first magnetic area 310 is corresponding to a position of the second magnetic area 312. As shown in FIG. 7, a magnetic pole of an end of the first magnetic area 310 facing the second magnetic area 312 is opposite to a magnetic pole of an end of the second magnetic area 312 facing the first magnetic area 310, such that a magnetic attraction force is generated between the first magnetic area 310 and the second magnetic area 312. It should be noted that the magnetic pole of an end of the first magnetic area 310 facing the second magnetic area 312 may be a north magnetic pole or a south magnetic pole, and the magnetic pole of an end of the second magnetic area 312 facing the first magnetic area 310 may be a south magnetic pole or a north magnetic pole correspondingly according to practical applications. In this embodiment, the first magnetic area 310 may be a magnetic induction material (e.g. iron or other metals), a magnet or an electromagnet, and the second magnetic area 312 may be a magnet.

When the liquid supply mechanism 30 is assembled completely and the chamber 308 contains the cooling liquid 32, the magnetic attraction force generated between the first magnetic area 310 and the second magnetic area 312 balances with the hydraulic pressure generated by the cooling liquid 32. At this time, the plunger 304 stays static in the chamber 308 . When the cooling liquid of the liquid cooling system 1 reduces and then the hydraulic pressure reduces, the magnetic attraction force generated between the first magnetic area 310 and the second magnetic area 312 will pull the plunger 304 to move, so as to inject the cooling liquid 32 from the chamber 308 into one of the liquid cooling head 10, the radiator 12, the pump 14, the liquid storage box 16 and the tubes 18. In other words, the liquid supply mechanism 30 of the invention can supply the cooling liquid to the liquid cooling system 1 automatically when the cooling liquid is insufficient, so as to prevent the liquid cooling system 1 from being damaged due to insufficient cooling liquid. When the magnetic attraction force generated between the first magnetic area 310 and the second magnetic area 312 balances with the hydraulic pressure generated by the cooling liquid 32 again, the plunger 304 stops moving.

In this embodiment, the first magnetic area 310 may be detachably disposed on a bottom of the casing 300. When a user wants to supply the cooling liquid 32 to the liquid supply mechanism 30, the user may detach the first magnetic area 310 from the bottom of the casing 300 first, so as to prevent the magnetic attraction force generated between the first magnetic area 310 and the second magnetic area 312 from hindering the supply of the cooling liquid 32.

As mentioned in the above, the liquid supply mechanism of the invention is selectively connected to one of the liquid cooling head, the radiator, the pump, the liquid storage box and the tubes. When the cooling liquid reduces and then the hydraulic pressure of the liquid cooling system reduces, the liquid supply mechanism utilizes the magnetic repulsive force or the magnetic attraction force to drive the plunger to move, so as to inject the cooling liquid from the chamber into the liquid cooling system. In other words, the liquid supply mechanism of the invention can supply the cooling liquid to the liquid cooling system automatically when the cooling liquid is insufficient, so as to prevent the liquid cooling system from being damaged due to insufficient cooling liquid.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid supply mechanism comprising:
a casing having a liquid outlet;
a cover connected to the casing, a chamber being formed between the casing and the cover, the chamber communicating with the liquid outlet, the cover having a first magnetic area; and
a plunger movably disposed in the chamber, the plunger having a second magnetic area, a position of the first magnetic area being corresponding to a position of the second magnetic area, a magnetic pole of an end of the first magnetic area facing the second magnetic area being identical to a magnetic pole of an end of the second magnetic area facing the first magnetic area, such that a magnetic repulsive force is generated between the first magnetic area and the second magnetic area.

2. The liquid supply mechanism of claim 1, wherein the first magnetic area is a magnet or an electromagnet, and the second magnetic area is a magnet.

3. The liquid supply mechanism of claim 1, further comprising a washer sleeved on an outer wall of the plunger and abutting against an inner wall of the casing.

4. The liquid supply mechanism of claim 1, wherein the casing has a third magnetic area, the second magnetic area is located between the first magnetic area and the third magnetic area, a magnetic pole of an end of the second magnetic area facing the third magnetic area is opposite to a magnetic pole of an end of the third magnetic area facing the second magnetic area, such that a magnetic attraction force is generated between the second magnetic area and the third magnetic area.

5. The liquid supply mechanism of claim 4, wherein the third magnetic area is a magnetic induction material, a magnet or an electromagnet.

6. The liquid supply mechanism of claim 4, wherein the third magnetic area is detachably disposed on a bottom of the casing.

7. A liquid cooling system comprising:
a liquid cooling head;
a radiator;
a pump;
a liquid storage box;
a plurality of tubes connected between the liquid cooling head, the radiator, the pump and the liquid storage box; and
a liquid supply mechanism selectively connected to one of the liquid cooling head, the radiator, the pump, the liquid storage box and the tubes, the liquid supply mechanism comprising:
a casing having a liquid outlet;
a cover connected to the casing, a chamber being formed between the casing and the cover, the chamber communicating with the liquid outlet, the cover having a first magnetic area; and
a plunger movably disposed in the chamber, the plunger having a second magnetic area, a position of the first magnetic area being corresponding to a position of the second magnetic area, a magnetic pole of an end of the first magnetic area facing the second magnetic area being identical to a magnetic pole of an end of the second magnetic area facing the first magnetic area, such that a magnetic repulsive force is generated between the first magnetic area and the second magnetic area.

8. The liquid cooling system of claim 7, wherein the first magnetic area is a magnet or an electromagnet, and the second magnetic area is a magnet.

9. The liquid cooling system of claim 7, wherein the liquid supply mechanism further comprises a washer sleeved on an outer wall of the plunger and abutting against an inner wall of the casing.

10. The liquid cooling system of claim 7, wherein the casing has a third magnetic area, the second magnetic area is located between the first magnetic area and the third magnetic area, a magnetic pole of an end of the second magnetic area facing the third magnetic area is opposite to a magnetic pole of an end of the third magnetic area facing the second magnetic area, such that a magnetic attraction force is generated between the second magnetic area and the third magnetic area.

11. The liquid cooling system of claim 10, wherein the third magnetic area is a magnetic induction material, a magnet or an electromagnet.

12. The liquid cooling system of claim 10, wherein the third magnetic area is detachably disposed on a bottom of the casing.

13. A liquid supply mechanism comprising:
a casing having a liquid outlet and a first magnetic area;
a cover connected to the casing, a chamber being formed between the casing and the cover, the chamber communicating with the liquid outlet; and
a plunger movably disposed in the chamber, the plunger having a second magnetic area, a position of the first magnetic area being corresponding to a position of the second magnetic area, a magnetic pole of an end of the first magnetic area facing the second magnetic area being opposite to a magnetic pole of an end of the second magnetic area facing the first magnetic area, such that a magnetic attraction force is generated between the first magnetic area and the second magnetic area.

14. The liquid supply mechanism of claim 13, wherein the first magnetic area is a magnetic induction material, a magnet or an electromagnet, and the second magnetic area is a magnet.

15. The liquid supply mechanism of claim 13, further comprising a washer sleeved on an outer wall of the plunger and abutting against an inner wall of the casing.

16. The liquid supply mechanism of claim 13, wherein the first magnetic area is detachably disposed on a bottom of the casing.

17. A liquid cooling system comprising:
a liquid cooling head;
a radiator;
a pump;
a liquid storage box;
a plurality of tubes connected between the liquid cooling head, the radiator, the pump and the liquid storage box; and
a liquid supply mechanism selectively connected to one of the liquid cooling head, the radiator, the pump, the liquid storage box and the tubes, the liquid supply mechanism comprising:
a casing having a liquid outlet and a first magnetic area;
a cover connected to the casing, a chamber being formed between the casing and the cover, the chamber communicating with the liquid outlet; and
a plunger movably disposed in the chamber, the plunger having a second magnetic area, a position of the first magnetic area being corresponding to a position of the second magnetic area, a magnetic pole of an end of the first magnetic area facing the second magnetic area being opposite to a magnetic pole of an end of the second magnetic area facing the first magnetic area, such that a magnetic attraction force is generated between the first magnetic area and the second magnetic area.

18. The liquid cooling system of claim 17, wherein the first magnetic area is a magnetic induction material, a magnet or an electromagnet, and the second magnetic area is a magnet.

19. The liquid cooling system of claim 17, further comprising a washer sleeved on an outer wall of the plunger and abutting against an inner wall of the casing.

20. The liquid cooling system of claim 17, wherein the first magnetic area is detachably disposed on a bottom of the casing.
